(19) United States
(12) Patent Application Publication
(10) Pub. No.: US 2025/0293043 A1
(43) Pub. Date: Sep. 18, 2025

(54) METHOD OF MANUFACTURING SEMICONDUCTOR DEVICE

(71) Applicant: Kioxia Corporation, Tokyo (JP)

(72) Inventors: Toshiyuki SASAKI, Yokkaichi Mie (JP); Hiroshi NAMBU, Yokkaichi Mie (JP)

(73) Assignee: Kioxia Corporation, Tokyo (JP)

(21) Appl. No.: 19/070,651

(22) Filed: Mar. 5, 2025

(30) Foreign Application Priority Data
Mar. 18, 2024 (JP) 2024-041898

(51) Int. Cl. H01L 21/311; H10B 43/27

(52) U.S. Cl. CPC H01L 21/31116; H10B 43/27

(57) ABSTRACT

A method of manufacturing a semiconductor device includes: introducing a first gas containing alcohol or a second gas containing the first gas and a halogen element to form a surface layer on an inner bottom surface of a depression on an object cooled at a temperature of 0° C. or less; introducing the second gas or a third gas containing a rare-gas element, generating the first plasma from the second gas or the third gas, and processing the inner bottom surface by etching using a first plasma; and alternately switching between the forming the surface layer and the processing the inner bottom surface.

### CROSS REFERENCE TO RELATED APPLICATIONS

This application is based upon and claims the benefit of priority from Japanese Patent Application No. 2024-041898, filed on Mar. 18, 2024; the entire contents of which are incorporated herein by reference.

### FIELD

Embodiments relate to a method of manufacturing a semiconductor device.

### BACKGROUND

A known example technology in a method of manufacturing a semiconductor device such as a 3D memory, includes forming a depression or an opening of an object by etching using etching gas containing a fluorinated hydrocarbon compound.

### BRIEF DESCRIPTION OF THE DRAWINGS

FIG. 1 is a flowchart to explain an example method of manufacturing a semiconductor device in a first embodiment.

FIG. 2 is a cross-sectional schematic diagram illustrating an example structure of an object.

FIG. 3 is a schematic diagram illustrating an example configuration of a semiconductor manufacturing apparatus.

FIG. 4 is a timing chart to explain an example etching method in the first embodiment.

FIG. 5 is a cross-sectional schematic diagram to explain an alcohol-containing gas introduction step (S2-1).

FIG. 6 is a cross-sectional schematic diagram to explain differences in a shape of a surface layer due to different gas conditions supplied to the object.

FIG. 7 is a cross-sectional schematic diagram to explain differences in the shape of the surface layer due to different gas conditions supplied to the object.

FIG. 8 is a cross-sectional schematic diagram to explain an etching step (S2-2).

FIG. 9 is a cross-sectional schematic diagram to explain a memory layer formation step.

FIG. 10 is a flowchart to explain a further example method of manufacturing the semiconductor device in the first embodiment.

FIG. 11 is a timing chart to explain an example etching method in the further example of the first embodiment.

FIG. 12 is a flowchart to explain an example method of manufacturing a semiconductor device in a second embodiment.

FIG. 13 is a timing chart to explain an example etching method in the second embodiment.

FIG. 14 is a flowchart to explain an example method of manufacturing a semiconductor device in a third embodiment.

FIG. 15 is a cross-sectional schematic diagram to explain a hydrophobic film formation step (S2-5) in the third embodiment.

FIG. 16 is a cross-sectional schematic diagram to explain a hydrophilization step (S2-6) in the third embodiment.

FIG. 17 is a cross-sectional schematic diagram to explain the etching step (S2-2) in the third embodiment.

FIG. 18 is a flowchart to explain an example method of manufacturing a semiconductor device in a fourth embodiment.

FIG. 19 is a cross-sectional schematic diagram to explain the example method of manufacturing the semiconductor device in the fourth embodiment.

### DETAILED DESCRIPTION

A method of manufacturing a semiconductor device according to an embodiment includes: introducing a first gas or the first gas and a second gas to form a surface layer on an inner bottom surface of a depression on a surface of an object cooled at a temperature of 0° C. or less, the first gas containing alcohol and the second gas containing a halogen element; introducing the second gas or a third gas, generating a first plasma from the second gas or the third gas, and processing the inner bottom surface by etching using the first plasma, the third gas containing a rare-gas element; and alternately switching between the forming the surface layer and the processing the inner bottom surface.

Embodiments are described below with reference to the drawings. A relationship between a thickness and a planar size of each component described in the drawings and a ratio of the thickness of each component may differ from actual ones. In addition, in the embodiments, substantially the same components are denoted by the same codes, and explanations will be omitted as appropriate.

### First Embodiment

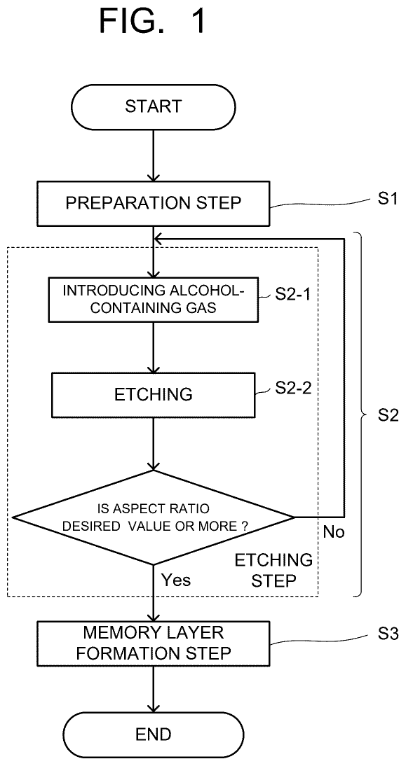

FIG. 1 is a flowchart to explain an example method of manufacturing a semiconductor device in a first embodiment. The semiconductor device is, for example, a three-dimensional memory. The example method of manufacturing the semiconductor device includes a preparation step (S1), an etching step (S2), and a memory layer formation step (S3).

### [Preparation Step]

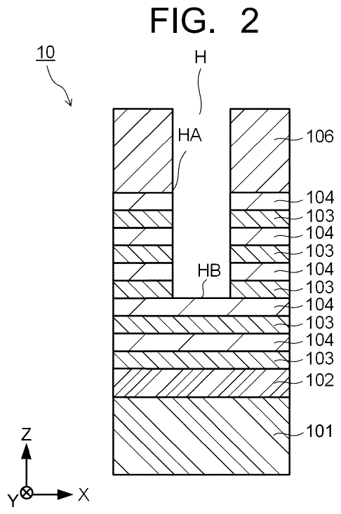

The preparation step includes preparing an object to be etched in the etching step. FIG. 2 is a cross-sectional schematic diagram illustrating an example structure of the object. FIG. 2 illustrates an X-axis, Y-axis, and Z-axis; the X, Y, and Z-axes are orthogonal to each other. FIG. 2 illustrates a part of an X-Z cross section of an object 10. The Z-axis is along a thickness direction of the object 10.

The object 10 includes a substrate 101, a base layer 102 provided on the substrate 101, a stack having a first layer 103 and a second layer 104 alternately stacked on the base layer 102, a mask layer 106 provided on the stack, and a depression H having an inner wall surface HA and an inner bottom surface HB and penetrating through the mask layer 106 to expose a part of the stack. The base layer 102, the first layer 103, the second layer 104, and the mask layer 106 are examples of films to be processed provided on the substrate 101, and the films to be processed are not limited to the configuration.

Examples of the substrate 101 include semiconductor substrates such as silicon substrates and silicon carbide substrates, insulating substrates such as glass, quartz, and sapphire substrates, and compound semiconductor substrates such as GaAs substrates can.

Examples of the base layer 102 include insulating films such as silicon oxide and silicon nitride films, and a conductive layer between insulating films. The base layer 102 does not necessarily have to be provided, in which case the first layer 103 is formed on the substrate 101. The first layer 103 may be formed on the base layer 102.

The first layer 103 is a sacrificial layer. The sacrificial layer is a region where the conductive layer will be formed later. For example, a silicon nitride film can be used as the first layer 103.

Examples of the second layer 104 include a silicon oxide film.

The mask layer 106 has a function as a mask for partly etching the stack. Examples of the mask layer 106 include an organic hard mask. The mask layer 106 may be removed after partly etching the stack.

The depression H is formed on a surface of the object. The depression H extends in the Z-axis direction. Examples of X-Y planar shapes of the depression H include circular and polygonal shapes. The inner bottom surface HB is formed on a surface of the first layer 103 or a surface of the second layer 104.

### [Etching Step]

### (Etching Apparatus)

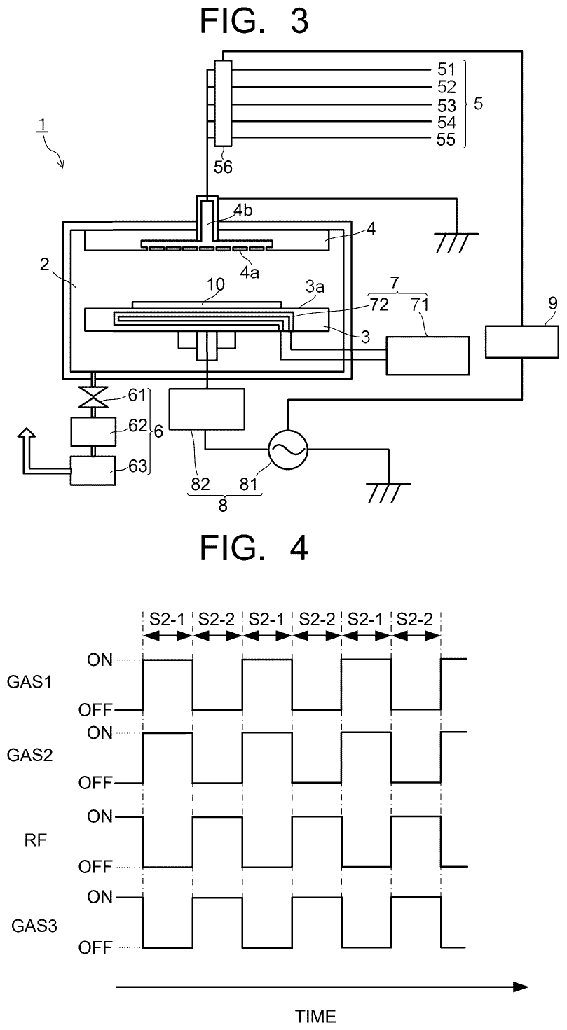

FIG. 3 is a schematic diagram illustrating an example configuration of a semiconductor manufacturing apparatus (etching apparatus), which can be used for the etching step. An etching apparatus 1 includes a processing chamber 2, an electrode 3, an electrode 4, a gas supply part 5, a gas discharge part 6, a cooling part 7, a power supply part 8, and a control part 9.

The processing chamber 2 is a space in which the object 10 can be etched using plasma (plasma etching). The processing chamber 2 may have a door (gate) for loading and unloading the object 10.

The electrode 3 is a lower electrode, and have a function as a stage on which the object 10 is mounted. The electrode 3 has a surface (a mounting surface) 3a on which the object 10 is mounted. The etching apparatus 1 may have an electrostatic chuck for holding the object 10.

The electrode 4 is an upper electrode. The electrode 4 has a surface 4a and an opening 4b for introducing gas into the processing chamber 2 through the electrode 4. The opening 4b has introduction ports on the surface 4a.

The gas supply part 5 has, for example, a gas supply source 51 that supplies a first gas, a gas supply source 52 that supplies a second gas, a gas supply source 53 that supplies a third gas, a gas supply source 54 that supplies a fourth gas, and a gas supply source 55 that supplies a fifth gas. The first gas to fifth gas are different from each other. Each of the gas supply sources 51 to 55 is connected to the processing chamber 2. The gas supply part 5 further includes a flow rate adjusting part 56 including mass flow controllers, and a flow rate of each of the first gas to fifth gas can be controlled by the corresponding mass flow controller. Examples of the gas supply sources 51 to 55 include cylinder cabinets. The gas supply part 5 supplies gases from the gas supply sources 51 to 55 to the processing chamber 2.

The first gas is a gas containing alcohol. Alcohol can form a liquid phase region at a pressure lower than the pressure of the liquid phase region of the second gas and at a temperature higher than the temperature of the liquid phase region of the second gas. Alcohol has the liquid phase region at a lower pressure and lower temperature than water (H₂O). Examples of alcohols include methanol or ethanol. Methanol and ethanol are preferred because they each have the liquid phase region at a pressure of 1 Pa or more and 10 Pa or less and a temperature of −75° C. or more and −55° C. or less, for example. Water (H₂O) is undesirable as the first gas because it becomes solid under the conditions described above. The first gas may further contain a halogen element. Examples of halogen elements include fluorine. The first gas may contain a fluorine-substituted alcohol, such as fluoromethanol, for example. Not limited to alcohol, the first gas may contain a gas mixture of, for example, ethane or butane and water. The first gas may be formed, for example, by vaporizing a liquid of the alcohol.

The second gas is a gas containing a halogen element. Examples of halogen elements include fluorine. The second gas contains, for example, fluoride gas. Examples of fluorides include hydrogen fluoride and fluorinated hydrocarbon compounds. Examples of fluorides are represented by a composition formula CₓH_{y}F_{z}, where C represents carbon, H represents hydrogen, F represents fluorine, x represents an integer of 0 or more, y represents an integer of 0 or more, and z represents an integer of 2 or more.

The third gas is a gas in a gaseous state at a temperature of a liquefaction temperature or less of the first gas and contains a rare-gas (noble gas) element. Examples of gases containing the rare-gas element include argon gas or krypton gas. The gas supply part 5 does not necessarily have the gas supply source 53.

The fourth gas is a gas containing a hydrogen element. Examples of gases containing the hydrogen element include hydrogen gas. Not limited to hydrogen gas, the fourth gas may be water vapor. The gas supply part 5 does not necessarily have the gas supply source 54.

The fifth gas is a gas containing an oxygen element. Examples of gases containing the oxygen element, include oxygen gas. The gas supply part 5 does not necessarily have the gas supply source 55.

The gas discharge part 6 has a function of reducing a pressure inside the processing chamber 2 to a vacuum state and can discharge the gas inside the processing chamber 2. The gas discharge part 6 has a valve 61, a turbo molecular pump 62, and a dry pump 63.

The cooling part 7 has, for example, a chiller 71 and a refrigerant tube 72 in the electrode 3. The chiller 71 can cool the object 10 by circulating a refrigerant through the refrigerant tube 72.

The power supply part 8 has a power supply 81 that supplies alternating voltage and a matching circuit 82 such as a matching box. The power supply part 8 has a function of supplying high-frequency voltage (RF) to the processing chamber 2 by matching impedance between the processing chamber 2 and the power supply 81 with the matching circuit 82. Examples of the high-frequency voltage include the alternating voltage having a frequency of 200 kHz or more and 200 MHz or less.

The control part 9 can control the gas supply part 5, the gas discharge part 6, the cooling part 7, and the power supply part 8. The control part 9 is composed of hardware such as a processor. Each operation may be stored as an operation program in a computer-readable recording medium such as a memory, and the hardware may execute each operation by reading the operation program stored in the recording medium as appropriate.

### (Etching Method)

As illustrated in FIG. 1, the etching step in the first embodiment includes a process of alternately switching between the alcohol-containing gas introduction step (S2-1) and the etching step (S2-2) until, for example, a ratio (aspect ratio) of a depth to width of the depression H reaches to a desired value or more.

FIG. 4 is a timing chart to explain an example etching method in the first embodiment. The alcohol-containing gas introduction step (S2-1) includes controlling the power supply part 8 by the control part 9 not to apply the high-frequency voltage between the electrodes 3 and 4 in the processing chamber 2, and controlling the flow rate adjusting part 56 by the control part 9 to introduce the first gas and second gas from the gas supply source 51 and gas supply source 52 respectively into the processing chamber 2 through the opening 4b (RF: OFF, GAS1: ON, GAS2: ON). The introduced gases are discharged after the alcohol-containing gas introduction step (S2-1) by controlling the valve 61, turbo molecular pump 62 and dry pump 63 by the control part 9. The alcohol-containing gas introduction step (S2-1) includes controlling the flow rate adjusting part 56 by the control part 9 to stop the introduction of the third gas into the processing chamber 2 (GAS3: OFF) before introducing the first gas and second gas. The fourth gas and fifth gas are explained here as not being used.

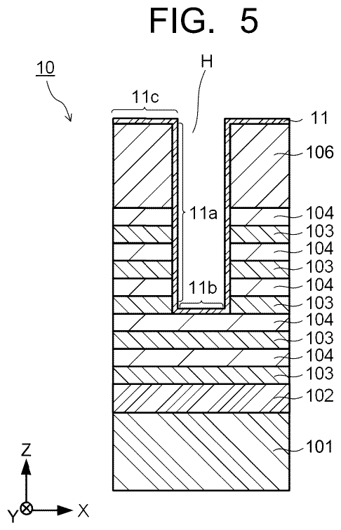

FIG. 5 is a cross-sectional schematic diagram to explain the alcohol-containing gas introduction step (S2-1). FIG. 5 illustrates a part of the X-Z cross section of the object 10. The alcohol-containing gas introduction step (S2-1) includes forming a surface layer 11 on a surface of the object 10 placed on the surface 3a of the electrode 3 in the processing chamber 2. The surface layer 11 has a region 11a extending along the inner wall surface HA of the depression H, a region 11b extending along the inner bottom surface HB of the depression H, and a region 11c extending along an upper surface of the mask layer 106 (an uppermost layer of the object 10).

The surface layer 11 is, for example, a liquid layer and contains a fluorine element and alcohol. The surface layer 11 is formed by supplying gas in a gaseous state that is not in a plasma or radical state and cooling the object 10 at the temperature and pressure in the liquid phase region of the first gas by the cooling part 7. The region 11b may be formed not only by the gas reaching the inner bottom surface HB directly, but also by the gas adhering on the inner wall surface HA to change into a liquid, and the changed liquid accumulating on the inner bottom surface HB according to gravity.

The liquefaction temperature of a mixed gas of the first gas and second gas can be determined uniquely according to the pressure of the processing chamber 2 and a vapor pressure curve of the mixed gas. The object 10 is preferably cooled, for example, at a pressure of 1 Pa or more and 10 Pa or less and a temperature of −75° C. or more and −55° C. or less. The third gas is inert at the liquefaction temperature or less of the mixed gas of the first gas and second gas.

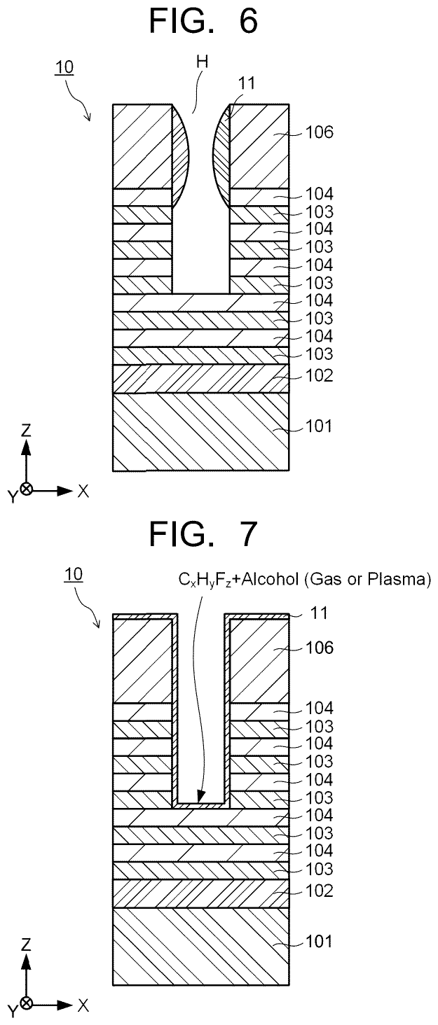

FIG. 6 and FIG. 7 are cross-sectional schematic diagrams to explain differences in shapes of the surface layer 11 due to different gas conditions supplied to the object 10. FIG. 6 and FIG. 7 each illustrate a part of the X-Z cross section of the object 10.

When the high-frequency voltage is supplied and plasma or radicals are generated from the second gas, the plasma or radicals of CₓH_{y}F_{z} have unpaired electrons, so steric hindrance around the unpaired electrons is small and they easily attach to the inner wall surface HA of the depression H and are unlikely to reach the inner bottom surface HB. Since plasma and radicals have a high probability of attachment, they can be formed on the object 10 regardless of the liquefaction temperature of the second gas (for example, −70° C.). Therefore, the surface layer 11 is formed thicker on an upper part of the inner wall surface HA, while it is less likely to be formed on the inner bottom surface HB, as illustrated in FIG. 6. In this case, an etching rate is reduced because the inner bottom surface HB is difficult to be etched.

In contrast, when the second gas that is not plasma or radicals is introduced without supplying the high-frequency voltage, the second gas can reach the inner bottom surface HB in the gaseous state, as illustrated in FIG. 2. Cooling the object 10 at the liquefaction temperature or less of the second gas (for example, −150° C.), causes the gas that reaches the inner wall surface HA and inner bottom surface HB to be a liquid or solid, and thus form the surface layer 11. Therefore, it is easier to form the surface layer 11 on the inner bottom surface HB. In this case, the etching rate is improved because the inner bottom surface HB is more easily etched by the region 11b.

However, it is necessary to cool the object 10 at a high pressure and low temperature to form a liquid phase because the second gas has a high triple point pressure and a low triple point temperature. For example, the liquid phase of CHF₃ exists at a pressure of 450 mTorr, and a pressure of 5 Torr or more is required to form the liquid phase by cooling at a temperature of −135° C. or less. This causes a deterioration in productivity of semiconductor devices.

Therefore, in the alcohol-containing gas introduction step (S2-1), the first gas containing alcohol is introduced together with the second gas. For example, the first gas has a lower triple point pressure and a higher triple point temperature than the second gas, so the liquid phase can be formed at a temperature of −75° C. or more and −55° C. or less at a pressure of 1 Pa or more and 10 Pa or less, for example. This improves the productivity of semiconductor devices.

In the alcohol-containing gas introduction step (S2-1), the first gas and second gas are introduced separately and mixed but may be introduced after the first gas and second gas are mixed. When the gases are pre-mixed, it is easier to mix uniformly and to adjust a ratio of the first gas to the second gas. In the mixed gas, the ratio of the second gas is higher than that of the first gas. When the gases are pre-mixed, an etchant with low vapor pressure can be used, and the liquefaction temperature can be increased. Furthermore, when the gases are pre-mixed, clusters of the mixed gas can be formed to facilitate introduction into the depression H.

The etching step (S2-2) includes controlling the flow rate adjusting part 56 by the control part 9 to introduce the third gas from the gas supply source 53 into the processing chamber 2 through the opening 4b, and controlling the power supply 81 by the control part 9 to apply the high-frequency voltage between the electrodes 3 and 4 in the processing chamber 2 from the power supply part 8 (RF: ON, GAS3: ON). Before introducing the third gas, the control part 9 controls the flow rate adjusting part 56 to stop the introduction of the first gas and second gas into the processing chamber 2 (GAS1: OFF, GAS2: OFF). The introduced gas is discharged after the etching step (S2-2) by controlling the valve 61, turbo molecular pump 62 and dry pump 63 by the control part 9.

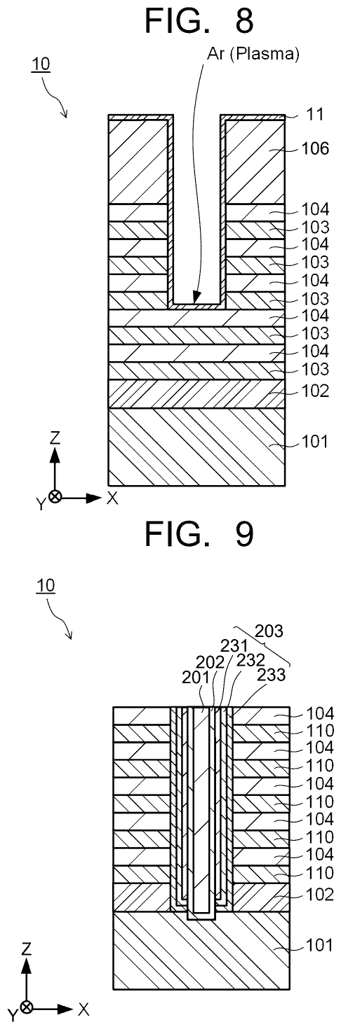

FIG. 8 is a cross-sectional schematic diagram to explain the etching step (S2-2). FIG. 8 illustrates a part of the X-Z cross section of the object 10. The etching step (S2-2) includes generating plasma from the third gas, and etching the object 10 and surface layer 11 by etching using plasma (argon plasma in FIG. 8).

The movement of ions in the plasma toward the electrode 3 are accelerated. Therefore, the first layer 103 and second layer 104 are mainly etched together with the regions 11b and 11c by the etching step (S2-2). Furthermore, the etching step (S2-2) can process the inner bottom surface HB of the depression H to increase an aspect ratio of the depression H.

In the alcohol-containing gas introduction step (S2-1), only the first gas is introduced to form the surface layer 11, and in the etching step (S2-2), the second gas is introduced instead of the third gas, and the inner bottom surface HB of the depression H may be processed by etching using plasma generated from the second gas.

a time period of the alcohol-containing gas introduction step (S2-1), a time period of the etching step (S2-2), and timing for switching between the alcohol-containing gas introduction step (S2-1) and the etching step (S2-2) may be controlled, for example, according to data obtained by monitoring a thickness of the surface layer 11 in-situ using an ellipsometer or other measuring instruments and obtaining data showing a relationship among respective thicknesses of the regions 11a to 11c. For example, it is preferable to switch between the alcohol-containing gas introduction step (S2-1) and the etching step (S2-2) according to the data before etching stops due to lack of the surface layer 11.

As described above, alternately switching the alcohol-containing gas introduction step (S2-1) and etching step (S2-2), enables improving the etching rate to achieve high-speed etching even when forming the depression H with a high aspect ratio.

### (Memory Layer Formation Step)

FIG. 9 is a cross-sectional schematic diagram to explain the memory layer formation step. FIG. 9 illustrates a part of the X-Z cross section of the object 10. The memory layer formation step includes forming a memory film 203, a semiconductor channel layer 202, and a core insulating film 201 in the depression H in this order, the memory film 203 including a block insulating film 233, a charge storage layer 232, and a tunnel insulating film 231. The core insulating film 201, semiconductor channel layer 202, and memory film 203 function as a memory layer forming a memory cell.

Examples of the core insulating film 201 include a silicon oxide film. Examples of the semiconductor channel layer 108 include a polysilicon layer. Examples of the tunnel insulating film 231 include a multilayer film having a silicon oxide film and a silicon oxynitride film. Examples of the charge storage layer 232 include a silicon nitride film. Examples of the block insulating film 233 include a silicon oxide film.

After forming the memory film 203, the first layer 103 is removed to form a cavity between the second layers 104, and a conductive layer 110 is formed by stacking conductive films in the cavity. The conductive layer 110 has a function as a gate electrode (word line), for example. Furthermore, contact plugs, wiring, interlayer insulating films, and other components are formed on the substrate 101. This enables the semiconductor device to be manufactured.

Although a memory hole where a memory layer is formed is shown as an example of the depression H in this embodiment, this embodiment is not limited to be applied to memory holes. For example, this embodiment can be applied to various types of depressions such as a slit (ST) for replacing a sacrificial layer with the conductive layer 110 and a hole for forming a contact plug connected to the conductive layer 110.

### Further Example of First Embodiment

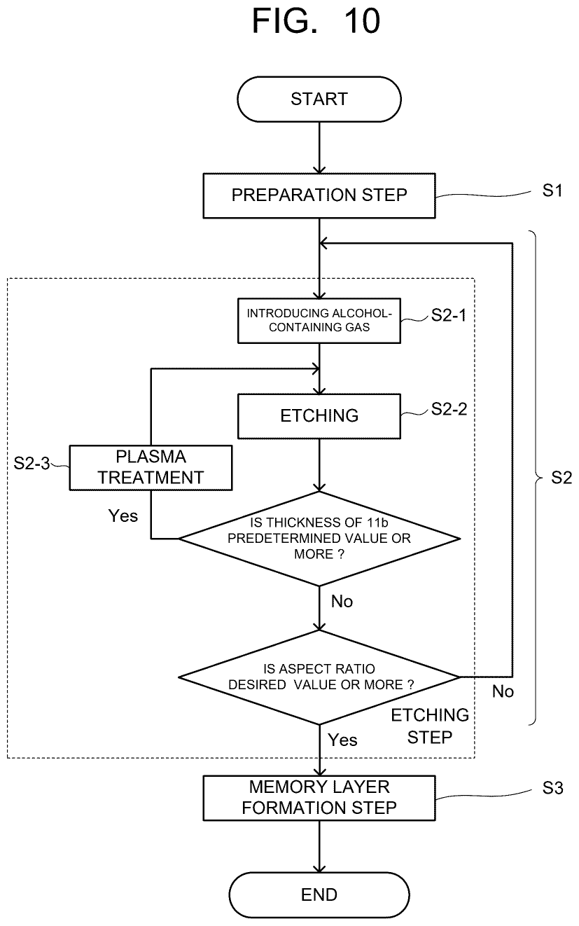

FIG. 10 is a flowchart to explain a further example method of manufacturing the semiconductor device in the first embodiment. The further example method of manufacturing the semiconductor device, includes the preparation step (S1), the etching step (S2), and the memory layer formation step (S3). Since the preparation step and the memory layer formation step are the same as in the first embodiment, the explanation is omitted in this embodiment.

### [Etching Step]

The etching step in the further example of the first embodiment can be performed using the etching apparatus 1 illustrated in FIG. 3. As illustrated in FIG. 10, the etching step includes: the process of alternately switching the steps between the alcohol-containing gas introduction step (S2-1) and the etching step (S2-2) until, for example, the aspect ratio of the depression H reaches a desired value, and a plasma treatment step (S2-3) in which plasma treatment is performed between the alcohol-containing gas introduction step (S2-1) and the etching step (S2-2), for example, when the thickness of the region 11b of the surface layer 11 is a predetermined value or more, after the process of alternately switching the alcohol-containing gas introduction step (S2-1) and the etching step (S2-2).

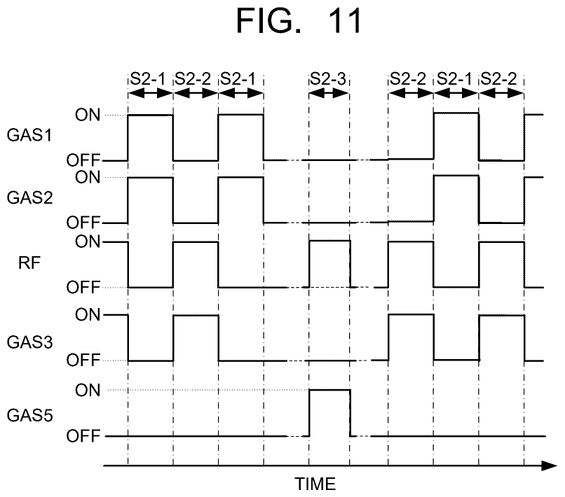

FIG. 11 is a timing chart to explain an example etching method in the further example of the first embodiment. The alcohol-containing gas introduction step (S2-1) and etching step (S2-2) are performed by alternately switching as in the etching method example described with reference to FIG. 4. Therefore, the explanation of the first embodiment will be used as appropriate.

The plasma treatment step (S2-3) includes controlling the flow rate adjusting part 56 by the control part 9 to introduce the fifth gas from the gas supply source 55 into the processing chamber 2 through the opening 4b, and controlling the power supply 81 by the control part 9 to apply the high-frequency voltage between the electrodes 3 and 4 in the processing chamber 2 from the power supply part 8 (RF: ON, GAS5: ON). Not limited to this process, the plasma treatment step (S2-3) may include controlling the flow rate adjusting part 56 by the control part 9 to introduce the third gas from the gas supply source 53 into the processing chamber 2 through the opening 4b, and controlling the power supply 81 by the control part 9 to apply the high-frequency voltage between the electrodes 3 and 4 in the processing chamber 2 from the power supply part 8. The introduced gas is discharged after the alcohol-containing gas introduction step (S2-1) by controlling the valve 61, turbo molecular pump 62 and dry pump 63 by the control part 9.

When the switching between the alcohol-containing gas introduction step (S2-1) and the etching step (S2-2) is continued, the region 11b, which is approximately perpendicular to a direction of plasma movement, may become too thick and the alcohol may inhibit etching.

In contrast, The plasma treatment step (S2-3) enable generating plasma from the third or fifth gas, and removing a part of carbon or alcohol in the region 11b by etching using the plasma of the third or fifth gas.

A time period of the plasma treatment step (S2-3) may, for example, be controlled according to data obtained by monitoring the thickness of the surface layer 11 in-situ using an ellipsometer or other measuring instruments and obtaining data showing the relationship among respective thicknesses of the regions 11a to 11c. For example, the plasma treatment step (S2-3) is preferably performed when the thickness of the region 11b is 10 nm or more and 20 nm or less.

As described above, the further example of the first embodiment includes performing the plasma treatment step (S2-3) between the alcohol-containing gas introduction step (S2-1) and the etching step (S2-2) to enable removing some of the alcohol contained in the surface layer 11 to prevent or reduce that processing of the inner bottom surface HB is inhibited. The further example of the first embodiment may includes performing again the process of alternately switching the alcohol-containing gas introduction step (S2-1) and the etching step (S2-2) may be performed again when the aspect ratio of the depression H is less than the desired value after the plasma treatment step (S2-3).

### Second Embodiment

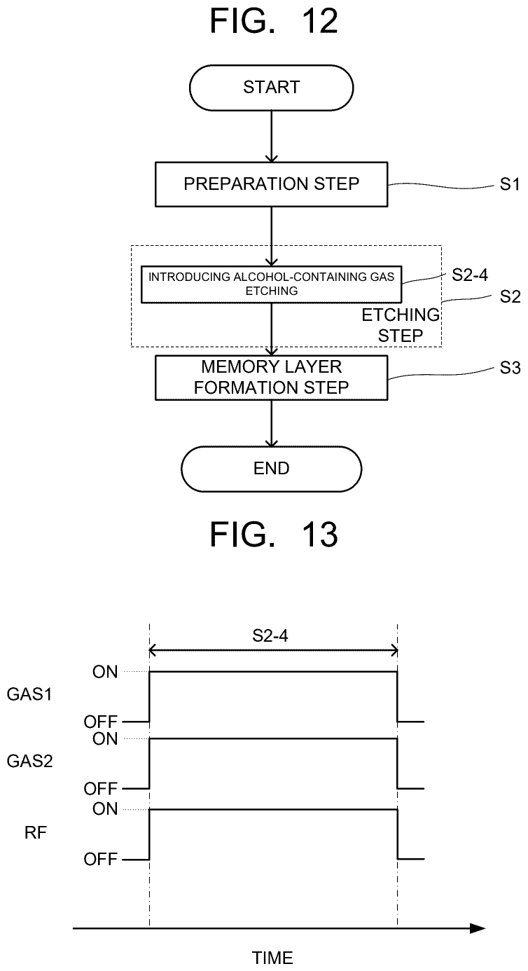

FIG. 12 is a flowchart to explain an example method of manufacturing a semiconductor device in a second embodiment. The example method of manufacturing the semiconductor device in the second embodiment, includes the preparation step (S1), the etching step (S2), and the memory layer formation step (S3). Since the preparation step and the memory layer formation step are the same as in the first embodiment, the explanation is omitted in this embodiment.

### [Etching Step]

The etching step in the second embodiment can be performed using the etching apparatus 1 illustrated in FIG. 3. As illustrated in FIG. 12, the etching step does not include the alcohol-containing gas introduction step (S2-1) and the etching step (S2-2), but instead of these steps, an alcohol-containing gas introduction and etching step (S2-4) is included.

FIG. 13 is a timing chart to explain an example etching method of the second embodiment. The alcohol-containing gas introduction and etching step (S2-4) includes controlling the power supply part 8 by the control part 9 to apply the high-frequency voltage between the electrodes 3 and 4 in the processing chamber 2, and controlling the flow rate adjusting part 56 by the control part 9 to introduce the first gas and second gas from the gas supply source 51 into the processing chamber 2 through the opening 4b (RF: ON, GAS1: ON, GAS2: ON). The third gas to fifth gas are not used. The introduced gases are discharged after the alcohol-containing gas introduction and etching step (S2-4) by controlling the valve 61, turbo molecular pump 62 and dry pump 63 by the control part 9. For other explanations of the alcohol-containing gas introduction and etching step (S2-4), the explanations of the alcohol-containing gas introduction step (S2-1) and etching step (S2-2) can be used as appropriate.

In the alcohol-containing gas introduction and etching step (S2-4), when the cooling part 7 cools the object 10 at a temperature of 0° C. or less with the temperature and pressure in the liquid phase region of the first gas, the first gas and second gas are introduced, and plasma is generated from the mixed gas, the plasma that reaches the inner wall surface HA and inner bottom surface HB changes into liquid to form the surface layer 11. A mixture of the second gas dissolved in liquid alcohol and ions derived from the second gas adheres to the inner wall surface HA and inner bottom surface HB, and the mixture adhering to the inner wall surface HA accumulates on the inner bottom surface HB according to gravity to form the surface layer 11. Therefore, it is easy to form the region 11b on the inner bottom surface HB. In this case, the inner bottom surface HB is more easily etched by the region 11b, making it easier to process the inner bottom surface HB and improving the etching rate.

### Third Embodiment

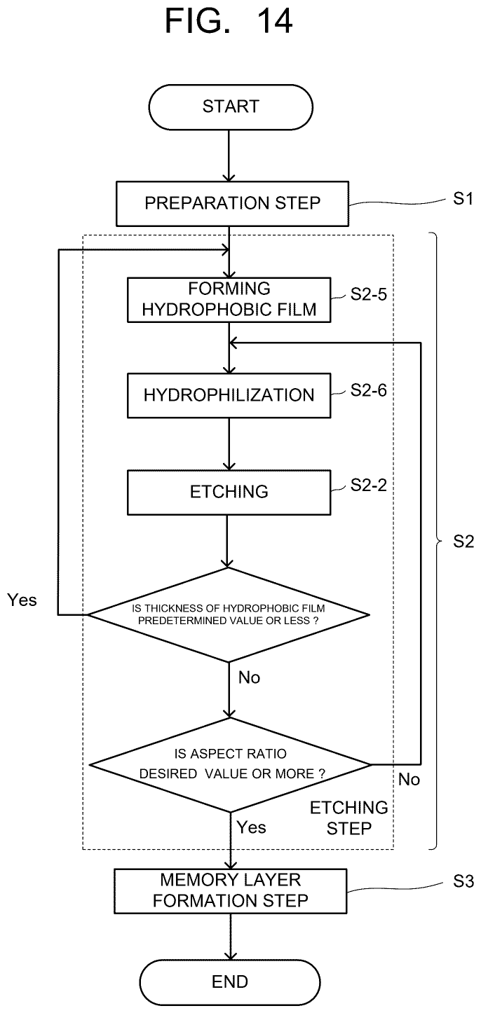

FIG. 14 is a flowchart to explain an example method of manufacturing a semiconductor device in a third embodiment. The example method of manufacturing the semiconductor device in the third embodiment, includes the preparation step (S1), the etching step (S2), and the memory layer formation step (S3). Since the preparation step and the memory layer formation step are the same as in the first embodiment, the explanation is omitted in this embodiment.

### [Etching Step]

The etching step in the third embodiment can be performed using the etching apparatus 1 illustrated in FIG. 3. As illustrated in FIG. 14, the etching step does not include the alcohol-containing gas introduction step (S2-1) but includes the etching step (S2-2), a hydrophobic film formation step (S2-5), and a hydrophilization step (S2-6).

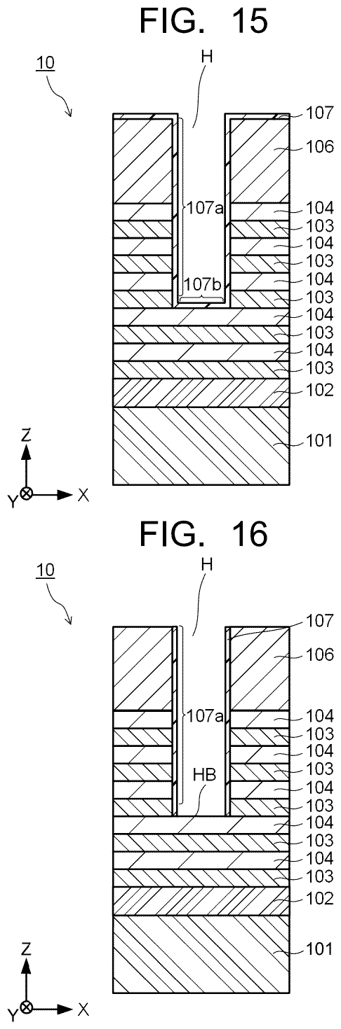

FIG. 15 is a cross-sectional schematic diagram to explain the hydrophobic film formation step (S2-5) in the third embodiment. FIG. 15 illustrates a part of the X-Z cross section of the object 10. The hydrophobic film formation step (S2-5) includes forming a hydrophobic film 107 on the inner wall surface HA and inner bottom surface HB of the depression H.

The hydrophobic film 107 has a region 107a on the inner wall surface HA and a region 107b on the inner bottom surface HB. A surface of the hydrophobic film 107 does not have any hydrophilic groups.

The hydrophobic film 107 contains a carbon element. The hydrophobic film 107 may be, for example, a fluorocarbon film.

The hydrophobic film 107 may be formed by supplying a silylation agent to the depression H. The silylation agent is, for example, a silane compound containing a silicon element, the hydrogen element, and the carbon element. The silylation agent may have Si—N bonds. Examples of silylation agents include aminosilanes compounds, chlorosilanes compounds, methoxysilanes compounds, and cyclic silanes compounds. The silylation agent may be supplied, for example, by the control part 9 controlling the power supply part 8 not to apply the high-frequency voltage between the electrodes 3 and 4 in the processing chamber 2, and by the control part 9 controlling the flow rate adjusting part 56 to introduce a gas containing the silylation agent from a gas supply source different from the gas supply sources 51 to 55 into the processing chamber 2 through the opening 4b.

Examples of aminosilanes compounds include compounds such as N-(trimethylsilyl)dimethylamine (TMSDMA), hexamethyldisilazane (HMDS), and n-octyldimethyl(dimethylamino)silane (ODMDMAS). The silylation agents may include compounds such as alkane represented by CₙH₂ₙ₊₂, (n is a natural number of 2 or more).

Examples of chlorosilanes compounds include octadecyltrichlorosilane (ODTC). Examples of methoxiranes compounds include octadecyltrimethoxysilane (ODMS). Examples of cyclic silanes compounds include N-methyl-aza-2,2,4-methylsilacyclopentane (CAZ).

For example, when the silylation agent is TMSDMA, Si—N bonds in molecules of TMSDMA are cleaved due to a sililation reaction when TMSDMA is supplied to the depression H and trimethylsilyl groups bond to an oxygen element and a nitrogen element on the surfaces of the inner wall surface HA and inner bottom surface HB. This can form the hydrophobic film 107 with the silicon element, the oxygen element, the carbon element, and the hydrogen element.

FIG. 16 is a cross-sectional schematic diagram to explain the hydrophilization step (S2-6) in the third embodiment. FIG. 16 illustrates a part of the X-Z cross section of the object 10. The hydrophilization step (S2-6) removes the region 107b while keeping at least a part of the region 107a to expose the inner bottom surface HB and hydrophilize the inner bottom surface HB.

An example of the hydrophilization step (S2-6) is performed by controlling the power supply part 8 by the control part 9 to apply the high-frequency voltage between the electrodes 3 and 4 in the processing chamber 2, controlling the flow rate adjusting part 56 by the control part 9 to introduce the fourth gas and fifth gas from the gas supply sources 54 and 55 into the processing chamber 2 through the opening 4b, and processing the hydrophobic film 107 by plasma treatment using plasma generated from a mixed gas of the fourth gas and the fifth gas. The plasma treatment can remove the region 107b while keeping at least a part of the region 107a because the region 107b is more easily removed than the region 107a.

Hydrophilization is performed by forming hydroxyl and amino groups on the surface of the inner bottom surface HB by the plasma treatment. In other words, the hydrophilized surface of the inner bottom surface HB has the hydrophilic group containing the hydrogen element.

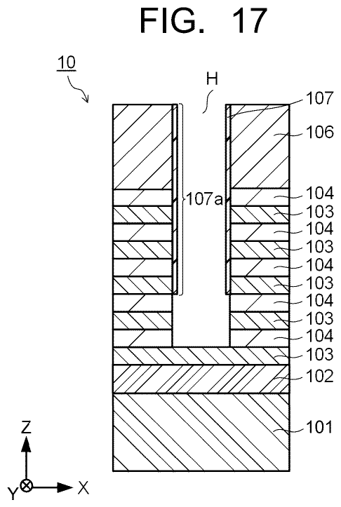

FIG. 17 is a cross-sectional schematic diagram to explain the etching step (S2-2) in the third embodiment. The etching step (S2-2) is performed after the hydrophilization step (S2-6) and by cooling the object 10 by the cooling part 7 at a temperature of 0° C. or less with the temperature and pressure in the liquid phase region of the first gas, controlling the power supply part 8 by the control part 9 to apply the high-frequency voltage between the electrodes 3 and 4 in the processing chamber 2, and controlling the flow rate adjusting part 56 by the control part 9 to introduce the second gas, third gas, or fourth gas from the gas supply source 52, gas supply source 53, or gas supply source 54 into the processing chamber 2 through the opening 4b, generating plasma from the second gas, third gas, or fourth gas, and processing the hydrophilized inner bottom surface HB by etching using the plasma. The object 10 may be cooled at a temperature of less than 30° C., for example. For other explanations of the etching step (S2-2) in the third embodiment, the explanation of the etching step (S2-2) in the first embodiment can be used as appropriate.

The etching step (S2-2) tends to cause the depression H to taper from the top to the bottom of the depression H. This taper is because the generated plasma is less likely to reach a lower part of the inner wall surface of the depression H and a part closer to the inner bottom surface of the depression H, and etching is more likely to proceed at an upper part of the inner wall surface of the depression H. As a result, the depression H tends to form dimensional differences from the top to the bottom of the depression H.

In contrast, the example method of the third embodiment includes forming the hydrophobic film 107 on the inner wall surface HA of the depression H to prevent or reduce adsorption of substances such as hydrogen fluoride and water vapor to prevent or impede the progress of the etching on the inner wall surface HA, and increasing the adsorption of substances such as hydrogen fluoride and water vapor on the inner bottom surface HB to enable the etching of the inner bottom surface HB. Therefore, the processing accuracy of the depression H can be improved even when forming the depression H with a high aspect ratio. As a result, it is possible to uniformly control the dimensions of the depression H from the top to the bottom of the depression H.

### Fourth Embodiment

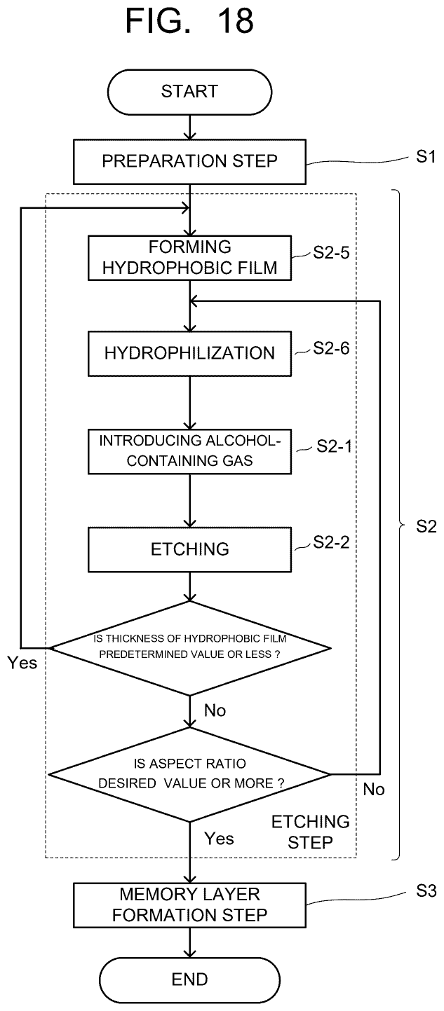

The first to third embodiments can be combined as appropriate. FIG. 18 is a flowchart to explain an example method of manufacturing a semiconductor device in a fourth embodiment. The example method of manufacturing a semiconductor device in a fourth embodiment, includes the preparation step (S1), the etching step (S2), and the memory layer formation step (S3). Since the preparation step and the memory layer formation step are the same as in the first embodiment, the explanation is omitted in this embodiment.

### [Etching Step]

The etching step in the fourth embodiment can be performed using the etching apparatus 1 illustrated in FIG. 3. The etching step includes the alcohol-containing gas introduction step (S2-1), the etching step (S2-2), the hydrophobic film formation step (S2-5), and the hydrophilization step (S2-6). Since each step is the same as in the first to third embodiments, the explanation is omitted in this embodiment.

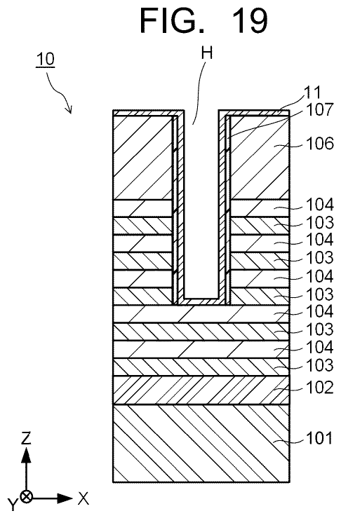

FIG. 19 is a cross-sectional schematic diagram to explain the example method of manufacturing the semiconductor device in the fourth embodiment. FIG. 19 illustrates a part of the X-Z cross section of the object 10. The etching step in the fourth embodiment, includes forming the hydrophobic film 107 by the hydrophobic film formation step (S2-5), hydrophilizing the inner bottom surface HB by the hydrophilization step (S2-6), and then forming the surface layer 11 on the hydrophobic film 107 and the hydrophilized inner bottom surface HB by the alcohol-containing gas introduction step (S2-1), and processing the inner bottom surface HB by the etching step (S2-2). In this case, the inner wall surface HA is less likely to be etched by the hydrophobic film 107, and the hydrophilized inner bottom surface HB is more likely to be etched by the surface layer 11, making it easier to process the inner bottom surface HB and improving the etching rate.

While certain embodiments of the present invention have been described herein, these embodiments have been presented by way of example only, and are not intended to limit the scope of the inventions. The novel embodiments described herein may be embodied in a variety of other forms; furthermore, various omissions, substitutions, and changes may be made without departing from the spirit of the inventions. The embodiments and modifications fall within the scope and spirit of the inventions and fall within the scope of the inventions as set forth in claims and their equivalents.

What is claimed is:

1. A method of manufacturing a semiconductor device, comprising:
introducing a first gas or the first gas and a second gas to form a surface layer on an inner bottom surface of a depression on a surface of an object cooled at a temperature of 0° C. or less, the first gas containing alcohol and the second gas containing a halogen element;
introducing the second gas or a third gas, generating a first plasma from the second gas or the third gas, and processing the inner bottom surface by etching using the first plasma, the third gas containing a rare-gas element; and
alternately switching between the forming the surface layer and the processing the inner bottom surface.

2. A method of manufacturing a semiconductor device, comprising:
introducing a first gas and a second gas, generating a second plasma from a mixed gas of the first gas and the second gas, processing an inner bottom surface by etching using the second plasma while forming a surface layer on the inner bottom surface of a depression on a surface of an object cooled at a temperature of 0° C. or less, the first gas containing alcohol and the second gas containing a halogen element.

3. A method of manufacturing a semiconductor device, comprising:
forming a hydrophobic film having a first region and a second region, the first region being on an inner wall surface of a depression on a surface of an object cooled at a temperature of 0° C. or less, and the second region being on an inner bottom surface of the depression;
removing the second region while keeping at least a part of the first region to expose the inner bottom surface and hydrophilize the inner bottom surface;
introducing a second gas, a third gas or a fourth gas, generating a third plasma from the second gas, the third gas or the fourth gas, and processing the hydrophilized inner bottom surface by etching using the third plasma, the second gas containing a halogen element, the third gas containing a rare-gas element, and the fourth gas containing a hydrogen element; and
alternately switching between the hydrophilizing the inner bottom surface and the processing the inner bottom surface.

4. The method according to claim 1, further comprising:
before the forming the surface layer,
forming a hydrophobic film having a first region and a second region, the first region being on an inner wall surface of the depression, and the second region being on the inner bottom surface; and
removing the second region while keeping at least a part of the first region to expose the inner bottom surface and hydrophilize the inner bottom surface.

5. The method according to claim 1, wherein
the surface layer is formed by introducing the first gas and the second gas.

6. The method according to claim 1, wherein
the first gas does not contain the halogen element, and
the surface layer is formed by introducing the first gas.

7. The method according to claim 1, further comprising:
between the forming the surface layer and the processing the inner bottom surface, introducing a third gas or a fifth gas, generating a fourth plasma from the third gas or the fifth gas, and removing a part of carbon or a part of the alcohol in the surface layer by etching using the fourth plasma, the third gas containing a rare-gas element and the fifth gas containing an oxygen element.

8. The method according to claim 1, wherein
the surface layer is formed by introducing the first gas and the second gas separately.

9. The method according to claim 1, wherein
the surface layer is formed by mixing the first gas and the second gas and then introducing them.

10. The method according to claim 1, wherein
the object is cooled at a temperature and a pressure in a liquid phase region of the first gas.

11. The method according to claim 1, wherein
the first gas contains fluoride gas represented by a composition formula CₓH_{y}F_{z},
where C represents carbon, H represents hydrogen, F represents fluorine, x represents an integer of 0 or more, y represents an integer of 0 or more, and z represents an integer of 2 or more.

12. The method according to claim 1, wherein
the first gas contains methanol, ethanol, or alcohol containing the halogen element.

13. The method according to claim 3, wherein
a surface of the hydrophobic film does not have any hydrophilic groups.

14. The method according to claim 3, wherein
the hydrophilized surface of the inner bottom surface has a hydrophilic group containing a hydrogen element.

15. The method according to claim 3, wherein
the hydrophobic film contains a carbon element.

16. The method according to claim 3, wherein
the hydrophobic film is formed by supplying a silylation agent to the depression.

17. The method according to claim 3, wherein
the second region is removed by introducing a fourth gas and a fifth gas and processing the second region by a fifth plasma generated from a mixed gas of the fourth gas and the fifth gas, the fourth gas containing a hydrogen element and the fifth gas containing an oxygen element, and
the inner bottom surface is hydrophilized by processing the inner bottom surface by the fifth plasma.

18. The method according to claim 1, wherein
the object has a stack having a silicon oxide film and a silicon nitride film, and
the inner bottom surface is formed on a surface of the silicon oxide film and a surface of the silicon nitride film.

19. The method according to claim 4, further comprising:
between the forming the surface layer and the processing the inner bottom surface, introducing a third gas or a fifth gas, generating a fourth plasma from the third gas or the fifth gas, and removing a part of carbon or a part of the alcohol in the surface layer by etching using the fourth plasma, the third gas containing a rare-gas element and the fifth gas containing an oxygen element.

20. The method according to claim 7, further comprising:
between the forming the surface layer and the processing the inner bottom surface, introducing a third gas or a fifth gas, generating a fourth plasma from the third gas or the fifth gas, and removing a part of carbon or a part of the alcohol in the surface layer by etching using the fourth plasma, the third gas containing a rare-gas element and the fifth gas containing an oxygen element.
